(19) United States
(12) Patent Application Publication
(10) Pub. No.: US 2025/0183511 A1
(43) Pub. Date: Jun. 5, 2025

(54) RESONATOR, OSCILLATOR, AND METHOD FOR MANUFACTURING RESONATOR

(71) Applicant: NEC Corporation, Tokyo (JP)

(72) Inventors: Yohei KAWAKAMI, Tokyo (JP); Tomohiro Yamaji, Tokyo (JP); Yoshihito Hashimoto, Tokyo (JP)

(73) Assignee: NEC Corporation, Tokyo (JP)

(21) Appl. No.: 18/956,607

(22) Filed: Nov. 22, 2024

(30) Foreign Application Priority Data
Dec. 4, 2023 (JP) 2023-204557

(51) Int. Cl. H01P 7/08; H03B 15/00; H10N 60/12

(52) U.S. Cl. CPC H01P 7/086; H03B 15/003; H10N 60/12

(57) ABSTRACT

A resonator includes a junction element including a Josephson junction and a fishbone-type waveguide coupled by the junction element.

This application is based upon and claims the benefit of priority from Japanese patent application No. 2023-204557, filed on Dec. 4, 2023, the disclosure of which is incorporated herein in its entirety by reference.

### TECHNICAL FIELD

The present disclosure relates to a resonator, an oscillator, and method for manufacturing a resonator.

### BACKGROUND ART

In superconducting circuits including quantum bits, coplanar waveguides (CPWs) are widely used as high-frequency transmission lines. CPWs have a two-dimensional structure in which a linear gap is provided in a superconductor evaporated on the surface of a substrate, and a linear superconductor for signal transmission is placed in the center of the gap. CPWs have inductance and capacitance proportional to the length of the waveguide. By appropriately designing the length of the waveguide based on the wavelength, it is possible to configure a distributed constant type resonator using CPWs. Alternatively, it is possible to configure a lumped constant type resonator using CPWs by adjusting the cavity inductance and/or capacitance. A CPW can be combined with a nonlinear inductance and used as a quantum bit (see, for example, Japanese Unexamined Patent Application, First Publication No. 2022-115740 A). A single Josephson junction or a Superconducting Quantum Interference Device (SQUID) in which two or more Josephson junctions form a closed path is used as the nonlinear inductance.

### SUMMARY

As described above, a CPW has a wide range of applications, but in a case where constructing a resonator, a CPW with a length equivalent to the wavelength of the resonance frequency, half the wavelength, or a quarter of the wavelength is required, so the chip shape is required to be long and large. In order to increase the degree of freedom in the chip shape and pattern design of a superconducting circuit including a resonator, it is common to give a part of the CPW a curvature and bend it (a meandering shape). However, in a case where there are multiple bends, or in a case where adjacent transmission lines are arranged in parallel for a long distance, a bent shape can produce a resonance mode different from the originally designed resonance, making the design difficult.

There is a demand for a smaller footprint in a superconducting circuit.

The present disclosure therefore aims to provide a resonator that solves the above problems.

According to a first example aspect of the present disclosure, a resonator includes a junction element including a Josephson junction, and a fishbone-type waveguide coupled by the junction element.

In an oscillator according to a second example aspect of the present disclosure, the resonator is oscillated by passing an AC current through the control line.

According to a third example aspect of the present disclosure, a method for manufacturing a resonator includes coupling a fishbone-type waveguide to a junction element including a Josephson junction.

According to the present disclosure, the length of the waveguide required for the resonator can be shortened by using a fishbone-type waveguide. This has the effect of reducing the footprint in a superconducting circuit.

### BRIEF DESCRIPTION OF THE DRAWINGS

FIG. 1 is a diagram showing an example of a chip layout of a resonator according to a first example embodiment of the present disclosure.

FIG. 2 is an enlarged view of the vicinity of a junction element of a resonator according to a first example embodiment of the present disclosure.

FIG. 3 is an enlarged view of the vicinity of a junction element in a case where the junction element according to the first example embodiment of the present disclosure is a SQUID.

FIG. 4 is an enlarged view of the vicinity of a junction element in a case where the junction element according to the first example embodiment of the present disclosure is composed of one Josephson junction.

FIG. 5 is a diagram showing an example of a chip layout of a resonator according to a second example embodiment of the present disclosure.

FIG. 6 is an enlarged view of the vicinity of a junction element of a resonator according to the second example embodiment of the present disclosure.

FIG. 7 is a diagram showing an example of the arrangement of a first branch line and a second branch line according to the second example embodiment of the present disclosure.

FIG. 8 is a diagram showing an example of the arrangement of the first branch line and the second branch line according to the second example embodiment of the present disclosure.

FIG. 9 is a diagram showing an example of the arrangement of a CPW according to the second example embodiment of the present disclosure.

FIG. 10 is a diagram showing an example of a chip layout of a resonator according to a third example embodiment of the present disclosure.

FIG. 11 is a diagram showing an example of a fishbone-type waveguide.

FIG. 12 is a diagram showing an example of a chip layout of a quantum bit according to the related art.

### EXAMPLE EMBODIMENT

### First Example Embodiment

Below, example embodiments of the present disclosure will be described in detail with reference to the drawings.

In the following description, a Josephson junction refers to an element having a structure in which a first superconductor and a second superconductor are bonded by a weakly bonded region such as a thin insulator. Here, the weakly bonded region may be an insulator, a minute superconductor, or a thin normal conductor. Moreover, a Superconducting Quantum Interference Device (SQUID) is an element in which two Josephson junctions are connected in a loop shape by a superconducting line. A part or all of the circuit described below is constructed using lines (wiring) made of a superconductor, and is used in a temperature environment of, for example, about 10 milliKelvin (mK) to achieve a superconducting state.

Moreover in the following description, “near” means within a range of 100 micrometers. For example, “near a node of an electric field” means within a range of 100 micrometers from the node of the electric field. In addition, “equal” and “equally spaced” are assumed to allow for manufacturing errors.

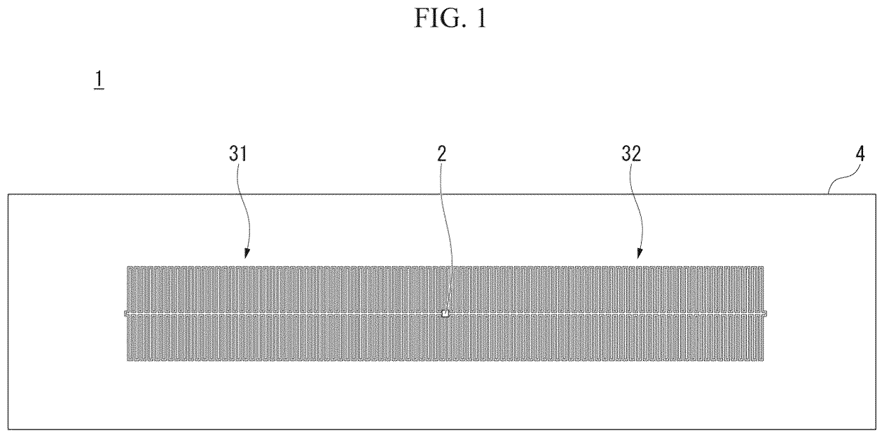

FIG. 1 shows an example of a chip layout of a resonator 1 according to this example embodiment. The resonator 1 includes a junction element 2, a fishbone-type waveguide 31, and a fishbone-type waveguide 32. The junction element 2, the fishbone-type waveguide 31, and the fishbone-type waveguide 32 are formed on a chip 4. The resonator 1 is a quantum bit that resonates with a standing wave corresponding to a half wavelength.

The junction element 2 is made of a Josephson junction. The fishbone-type waveguide 31 and the fishbone-type waveguide 32 are coupled by the junction element 2. The length of the fishbone-type waveguide 31 and the length of the fishbone-type waveguide 32 are equal to each other.

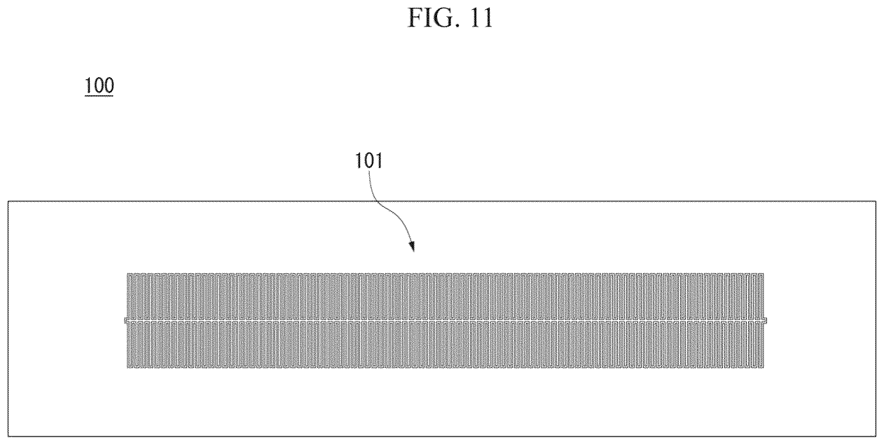

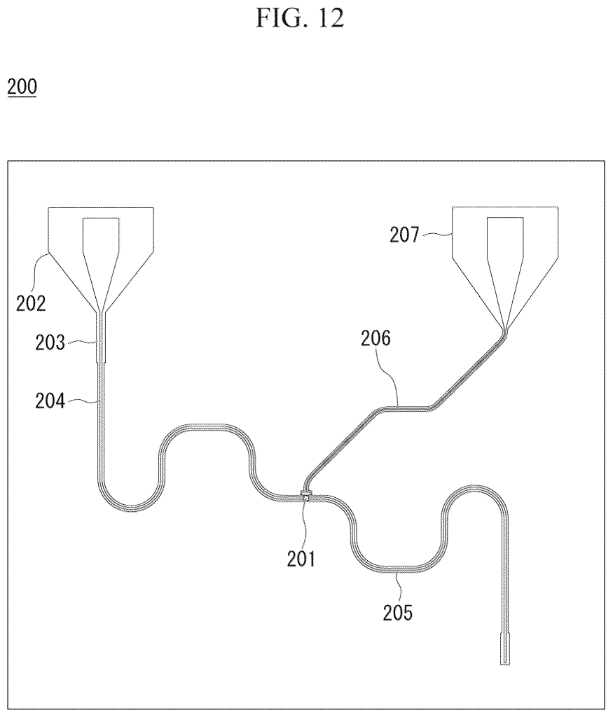

Now, referring to FIG. 11, the fishbone-type waveguide will be described. The resonant element 100 shown in FIG. 11 is a half-wavelength resonant element composed of a fishbone-type waveguide 101. The fishbone-type waveguide is composed of a central waveguide and multiple waveguides protruding from both sides at equal intervals. Each of the multiple protruding waveguides is called a stub. The stubs are preferably shorter than the overall length of the central waveguide. In the fishbone-type waveguide, the characteristic impedance and phase velocity can be adjusted arbitrarily by changing parameters such as the interval between adjacent stubs. The resonant element composed of the fishbone-type waveguide has an increased capacitance and inductance per unit length due to the contribution of the stubs. Therefore, the length of the waveguide of the resonant element composed of the fishbone-type waveguide is shorter than that of a normal waveguide having the same electrical characteristics. Even if the standing waves are of the same frequency, the wavelength of the standing wave on the fishbone-type waveguide is shorter than that of the standing wave on a normal waveguide. In this example embodiment, this is called the effective wavelength. The effective wavelength can be obtained by electromagnetic field simulation.

Returning to FIG. 1, the explanation of the configuration of the resonator 1 will continue. The fishbone-type waveguide 31 and the fishbone-type waveguide 32 are each a distributed constant line. In a case where the quantum bit is in operation, a standing wave is generated in the quantum bit. The fishbone-type waveguide 31 and the fishbone-type waveguide 32 each have a length corresponding to a quarter of the wavelength corresponding to the operating frequency of the resonator 1. In other words, they have a length that is a quarter of the effective wavelength in the fishbone-type waveguide corresponding to the operating frequency. Therefore, the resonator 1 is a quantum bit that resonates with a standing wave that corresponds to a half wavelength as a whole. The length of each of the fishbone-type waveguide 31 and the fishbone-type waveguide 32 is, for example, about 300 μm.

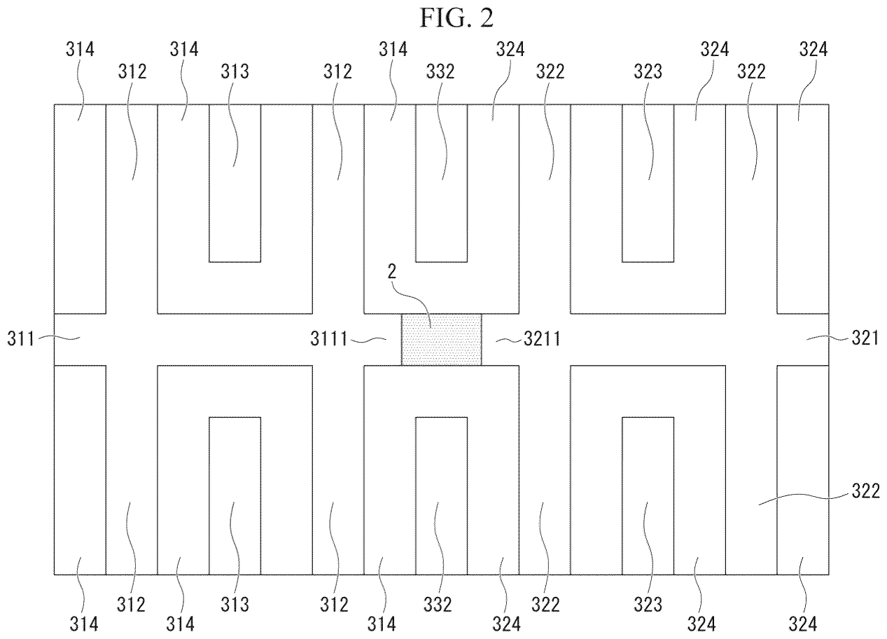

FIG. 2 shows an enlarged view of the vicinity of the junction element 2 of the resonator 1. In FIG. 2, the fishbone-type waveguide 31 is composed of a central waveguide 311 and multiple stubs 312. A ground conductor 313 is formed between the multiple stubs 312. The stubs 312 and the ground conductors 313 are arranged alternately by bending the substrate portion 314. Similarly, the fishbone-type waveguide 32 is composed of a central waveguide 321 and a plurality of stubs 322. A ground conductor 323 is formed between the plurality of stubs 322. The stubs 322 and the ground conductors 323 are arranged alternately by bending the substrate portion 324. A ground conductor 332 is formed in the region where the fishbone-type waveguide 31 and the fishbone-type waveguide 32 are coupled.

The central waveguide 311, the plurality of stubs 312, the plurality of ground conductors 313, the central waveguide 321, the plurality of stubs 322, and the plurality of ground conductors 323 are each a thin film of a superconducting material formed on a silicon substrate. On the other hand, the substrate portion 314 and the substrate portion 324 are each a portion where the silicon substrate is exposed after the thin film has been peeled off.

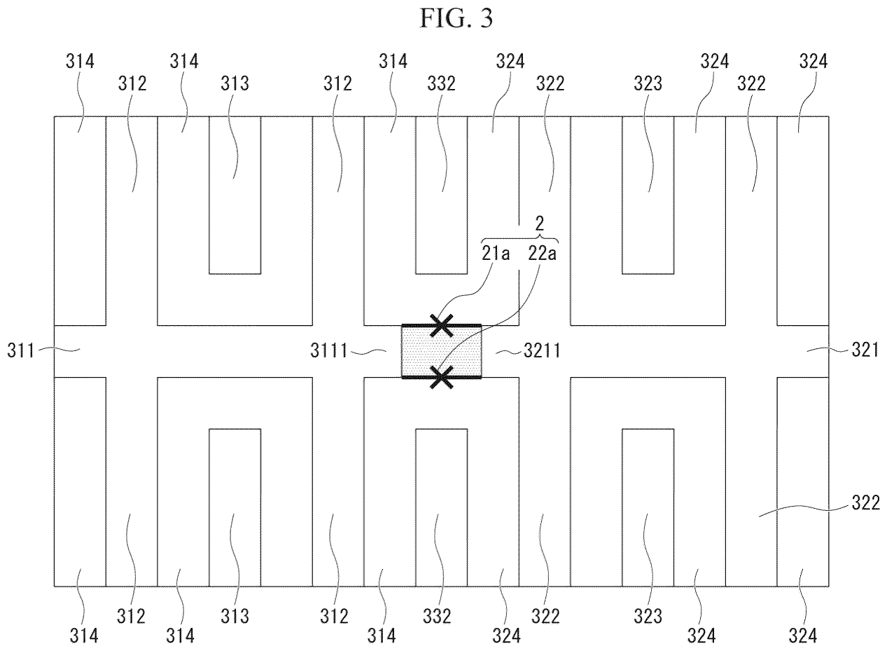

The junction element 2 couples the junction portion 3111 of the central waveguide 311 with the junction portion 3211 of the central waveguide 321. FIG. 3 shows an example in which the junction element 2 is a SQUID. In FIG. 3, the junction element 2 is made up of a Josephson junction 21a and a Josephson junction 22a. The Josephson junction 21a and the Josephson junction 22a respectively couple the junction portion 3111 with the junction portion 3211.

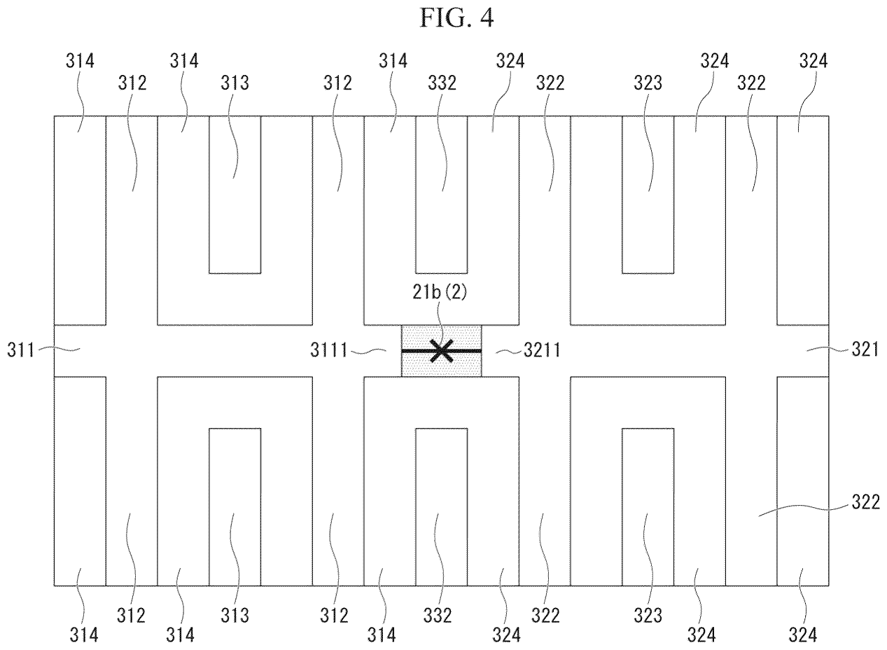

FIG. 4 shows an example in which the junction element 2 is made up of one Josephson junction 21b. The Josephson junction 21b couples the junction portion 3111 with the junction portion 3211.

Note that the resonator 1 is not limited to a quantum bit forming a half-wave resonator. The resonator 1 may be used in a quantum bit that forms a resonator with a wavelength other than a half wavelength, such as a quarter of the effective wavelength, by changing the lengths of the fishbone-type waveguide 31 and the fishbone-type waveguide 32.

For example, in this example embodiment, an example in which the length and shape of the fishbone-type waveguide 31 and the length and shape of the fishbone-type waveguide 32 are equal to each other has been described. That is, an example in which the junction element 2 is disposed at a quarter of the effective wavelength corresponding to the operating frequency of the resonator 1 has been described, but the disclosure is not limited to this. The lengths and shapes of the two fishbone-type waveguides coupled to both ends of the junction element 2 may be different from each other. That is, the junction element 2 may be disposed at a position other than a quarter of the effective wavelength corresponding to the operating frequency of the resonator 1.

It should be noted that one of the fishbone-type waveguide 31 and the fishbone-type waveguide 32 may be a coplanar waveguide (CPW). In that case, the fishbone-type waveguide and the CPW are coupled by the junction element 2.

As described above, the resonator 1 according to the example embodiment includes the junction element 2 made of a Josephson junction, and fishbone-type waveguides (in this example embodiment, the fishbone-type waveguide 31 and the fishbone-type waveguide 32) coupled by the junction element 2.

With this configuration, the resonator 1 according to the example embodiment can reduce the waveguide length required for the resonator by using the fishbone-type waveguide, and therefore the footprint can be reduced. Here, the fact that the footprint can be reduced means the footprint can be reduced compared to a superconducting circuit using only a CPW as a waveguide.

### Second Example Embodiment

A second example embodiment of the present disclosure will be described below in detail with reference to the drawings.

In this example embodiment, a case will be described in which the resonator is magnetically coupled to the junction element and further includes a control line to which a control signal is input. The same components as those in the first example embodiment are denoted by the same reference numerals, and the description of the same components and operations may be omitted.

Before describing the resonator 1A according to this example embodiment, a quantum bit including a control line according to the related technology will be described with reference to FIG. 12. FIG. 12 is a diagram showing an example of a chip layout of a quantum bit 200 according to the related technology. The quantum bit 200 includes a junction element 201, an input/output port 202, an input/output line 203, a partial waveguide 204, a partial waveguide 205, a control line 206, and a control port 207.

The input/output line 203 is a CPW. The CPW is impedance-matched to, for example, 50Ω. The partial waveguide 204 and the partial waveguide 205 are coupled by the junction element 201 at a position of a quarter of the effective wavelength corresponding to the operating frequency of the quantum bit 200. The partial waveguide 204, the junction element 201, and the partial waveguide 205 constitute a resonator. The control line 206 is arranged so that the tip of the control line 206 is near the junction element 201. The control line 206 is magnetically coupled to the junction element 201.

The control line 206 adjusts the resonance frequency (operating frequency) of the quantum bit 200. The resonance frequency of the quantum bit 200 can be set by inputting a direct current (DC) control signal from the control port 207. More specifically, the resonance frequency of the quantum bit 200 can be controlled by applying a magnetic field generated from the current flowing through the control line 206 to the junction element 201. In addition to frequency adjustment, the control line 206 is also used to apply an AC magnetic field to the junction element by passing an AC current of the resonance frequency or its harmonic to oscillate the resonator (the partial waveguide 204, the junction element 201, and the partial waveguide 205). The current passed through the control line 206 may be a current in which a DC current and an AC current are superimposed. In this case, the control line 206 becomes a path through which the energy stored in the resonator flows out to the outside, which causes a decrease in the internal Q value of the resonator. In a half-wave resonator, the center of the resonator becomes a node of the electric field. Therefore, by arranging the tip of the control line 206 near the center of the resonator, which is the node of the electric field, it is possible to reduce the outflow of energy.

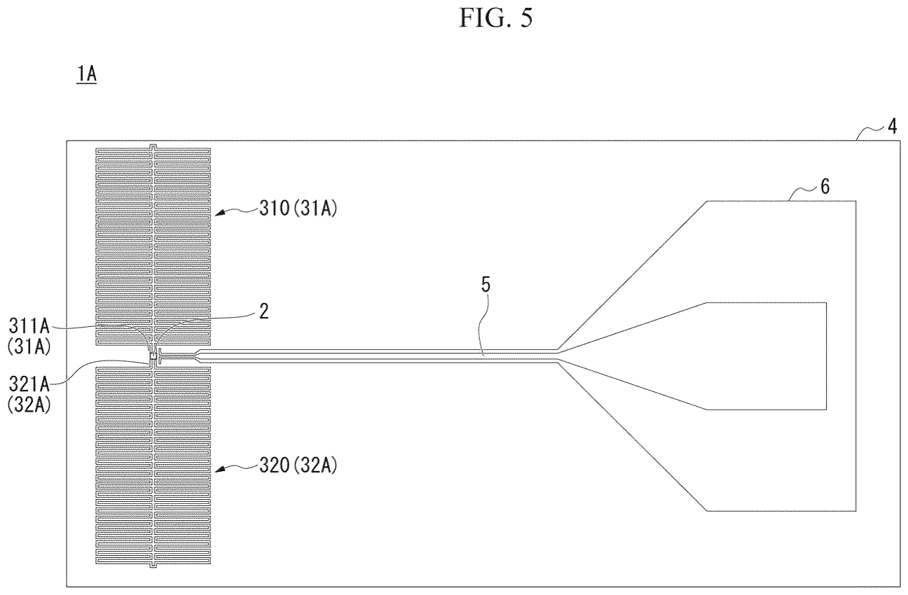

FIG. 5 is a diagram showing an example of a chip layout of the resonator 1A according to this example embodiment. The resonator 1A includes a junction element 2, a waveguide 31A, a waveguide 32A, a control line 5, and a control port 6. The junction element 2, the waveguide 31A, the waveguide 32A, the control line 5, and the control port 6 are formed on a chip 4. The function of the resonator 1A as a resonator is performed by the junction element 2, the waveguide 31A, and the waveguide 32A. The resonator 1A is a quantum bit that forms a half-wavelength resonator.

The waveguide 31A includes a fishbone-type waveguide 310 and a CPW 311A. The waveguide 32A includes a fishbone-type waveguide 320 and a CPW 321A. The fishbone-type waveguide 310 is coupled to the junction element 2 via the CPW 311A. The fishbone-type waveguide 320 is coupled to the junction element 2 via the CPW 321A. In other words, the two fishbone-type waveguides are each coupled to the junction element 2 via a CPW.

The fishbone-type waveguide 310 and the fishbone-type waveguide 320 are each a distributed constant line. The fishbone-type waveguide 310 and the fishbone-type waveguide 320 each have a length corresponding to a quarter of the effective wavelength corresponding to the operating frequency of the resonator 1A. Therefore, the resonator is a quantum bit that forms a distributed constant type resonator of half wavelength as a whole. The length of each of the fishbone-type waveguide 310 and the fishbone-type waveguide 320 is about 300 μm, for example.

The control line 5 is magnetically coupled to the junction element 2, and a control signal is input. The control line 5 can set the resonance frequency of the resonator 1A by inputting a control signal of direct current (DC). More specifically, the resonance frequency can be controlled by applying a magnetic field generated from a current flowing through the control line 5 to the junction element 2. The junction element 2 is a loop structure including multiple Josephson junctions, i.e., a SQUID. The resonance frequency of the SQUID can be controlled by applying a magnetic field to the SQUID to change the equivalent inductance of the SQUID. The control line 5 is also used to apply an AC magnetic field to the junction element 2 by passing an AC current of the resonance frequency or its harmonic frequency to oscillate the resonator (waveguide 31A and waveguide 32A). The current passed through the control line may be a current in which a DC current and an AC current are superimposed.

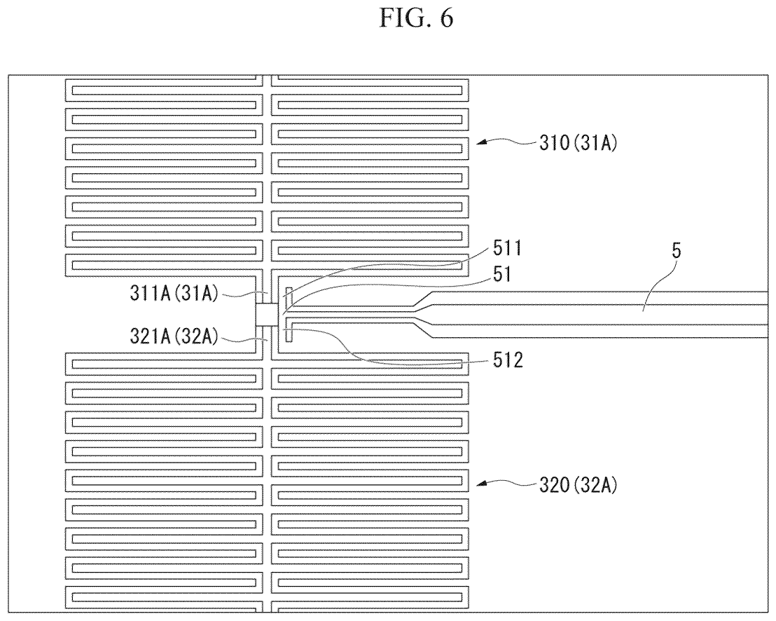

FIG. 6 shows an enlarged view of the vicinity of the junction element 2 of the resonator 1A. The tip 51 of the control line 5 branches into a first branch line 511 and a second branch line 512. The first branch line 511 and the second branch line 512 are arranged near the junction element 2 so as to be magnetically coupled to the junction element 2. In other words, the tip 51 of the control line 5 is arranged near the junction element 2. Here, the position where the junction element 2 is disposed is a quarter of the effective wavelength corresponding to the operating frequency of the resonator 1A (the position of the node of the electric field). In other words, the tip 51 of the control line 5 and the first branch line 511 and the second branch line 512 are disposed near the node of the electric field, which is a standing wave generated in the resonator 1A in a case where the resonator 1A is in operation. In the resonator 1A, by disposing the tip 51 of the control line 5 and the first branch line 511 and the second branch line 512 near the node of the electric field, it is possible to minimize the outflow of energy and prevent a decrease in the internal Q value of the resonator.

Furthermore, as described above, the two fishbone-type waveguides (fishbone-type waveguide 310 and fishbone-type waveguide 320) are coupled to the junction element 2 via the CPWs (CPW311A and CPW321A), respectively. The CPW 311A and CPW321A are each linear. The length of each of the CPW311A and CPW321A is such that the tip 51 of the control line 5 and the first branch line 511 and the second branch line 512 can be arranged near the junction element 2. The length is preferably 3 μm or more, and more preferably 5 μm or more. In order to minimize the effect on the resonance frequency of the resonator 1A, the length is preferably 1/50 or less of the wavelength corresponding to the resonance frequency, more preferably 1/100 or less, and even more preferably 1/500 or less. By arranging the linear CPW311A and CPW321A near the junction element 2, the tip 51 of the control line 5 and the first and second branch lines 511 and 512 can be arranged near the junction element 2.

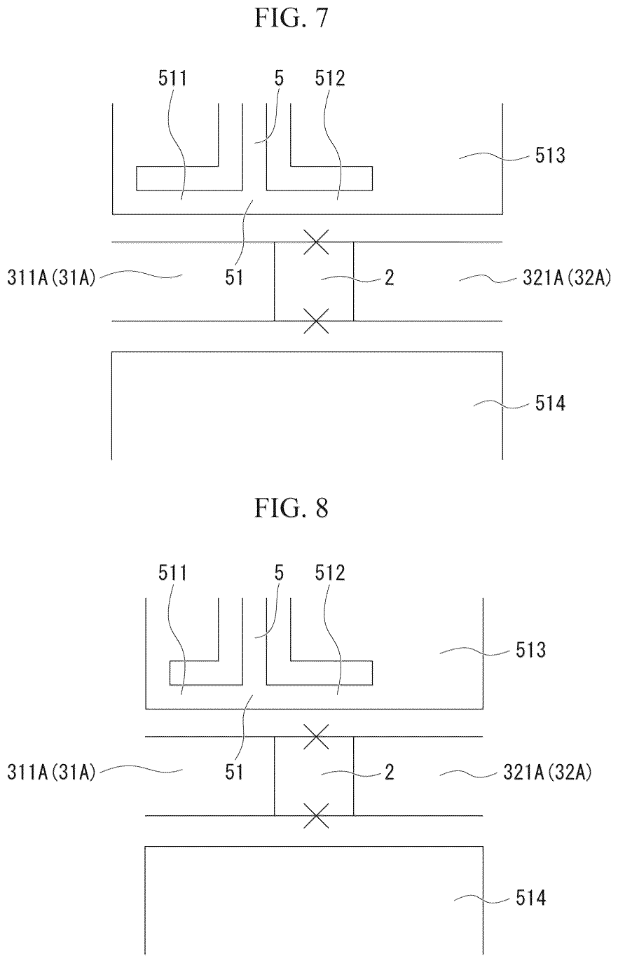

Now, referring to FIG. 7, the details of the arrangement of the first and second branch lines 511 and 512 will be described. The first branch line 511 and the second branch line 512 are arranged so that the current flowing through the first branch line 511 and the current flowing through the second branch line 512 are equal in amount and in opposite directions. Specifically, as shown in FIG. 7, the first branch line 511 and the second branch line 512 are arranged so as to be symmetrical with respect to the control line 5. The first branch line 511 is wired along the junction element 2, and the second branch line 512 is wired in the opposite direction to the first branch line 511. For this reason, the second branch line 512 is configured to be magnetically coupled to the junction element 2, while the first branch line 511 is configured not to be magnetically coupled to the junction element 2. More specifically, for example, as shown in FIG. 7, the control line 5 is a T-shaped line, and the first branch line 511 and the second branch line 512 branched at the tip 51 are arranged in a straight line. That is, the angle between the first branch line 511 and the non-branched portion of the control line 5 is 90 degrees, the angle between the second branch line 512 and the non-branched portion of the control line 5 is 90 degrees, and the angle between the first branch line 511 and the second branch line 512 is 180 degrees. These angles are ideal values, and in reality, a manufacturing error of ±10% or less of these angles is allowed.

Note that the CPW311A and the CPW321A are arranged so as to be symmetrical with respect to the junction element 2.

Note that the arrangement of the first branch line 511 and the second branch line 512 is not limited to the arrangement shown in FIG. 7. As another example, as shown in FIG. 8, the first branch line 511 and the second branch line 512 may be arranged so that the length of the first branch line 511 is shorter than the length of the second branch line 512. By making the length of the first branch line 511 shorter than the length of the second branch line 512, the areas of the first ground region 513 and the second ground region 514 can be made smaller than those of the arrangement shown in FIG. 7 while arranging the CPW311A and CPW321A so as to be symmetrical with respect to the junction element 2. Accordingly, the CPW311A and CPW321A can be shortened, and the size of the entire resonator can be reduced. Note that in FIG. 8, the CPW311A and CPW321A are arranged so as to be symmetrical with respect to the junction element 2.

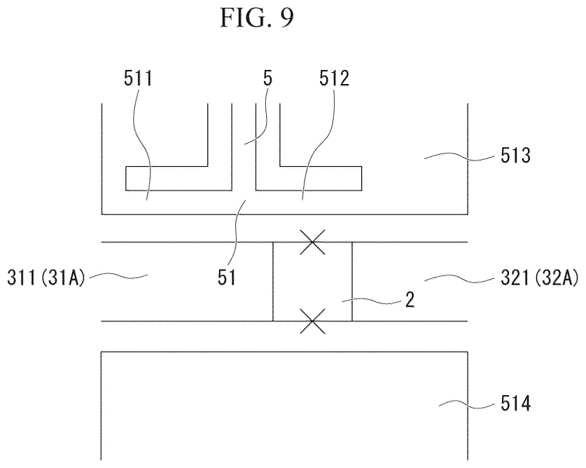

The arrangement of the CPW311A and CPW321A is not limited to the arrangement shown in FIG. 7. As another example, as shown in FIG. 9, the CPW311A and CPW321A may be arranged so that the length of the CPW321A is shorter than the length of the CPW311A. By making the length of the CPW 321A shorter than the length of the CPW 311A, the areas of the first ground region 513 and the second ground region 514 can be made smaller than those of the arrangement shown in FIG. 7. Accordingly, the size of the entire resonator can be made smaller. In FIG. 9, the first branch line 511 and the second branch line 512 are arranged symmetrically with respect to the control line 5.

The CPW 311A and the CPW 321A may be omitted from the configuration of the resonator 1A. In that case, the fishbone type waveguide 310 and the fishbone type waveguide 320 are directly coupled to the junction element 2, respectively. Even in that case, it is preferable that the tip 51 of the control line 5 is arranged as close to the junction element 2 as possible. In order to arrange the tip 51 of the control line 5 as close to the junction element 2 as possible, it is preferable that the tip 51 is arranged near the outside of each of the stubs of the fishbone type waveguide 310 and the fishbone type waveguide 320.

As described above, the control line 5 is also used to apply an alternating current magnetic field to the junction element 2 by passing an alternating current at the resonance frequency or its harmonic, thereby causing the resonators (waveguide 31A and waveguide 32A) to oscillate. In other words, the resonator (resonator 1A in this example embodiment) may be used as an oscillator that oscillates the resonator (resonator 1A in this example embodiment) by passing an AC current through the control line 5. In this oscillator, the two fishbone-type waveguides may be coupled to the junction element via coplanar waveguides, or the two fishbone-type waveguides may be directly coupled by the junction element.

### Third Example Embodiment

A third example embodiment of the present disclosure will be described below in detail with reference to the drawings.

In this example embodiment, a quantum bit is formed by coupling two waveguide structures by a Josephson junction as in the first example embodiment. However the case where the waveguide structure is a combination of a fishbone-type waveguide and a linear or meander-shaped CPW will be described. Note that the same components as those in the first example embodiment described above are given the same reference numerals, and descriptions of the same components and operations may be omitted.

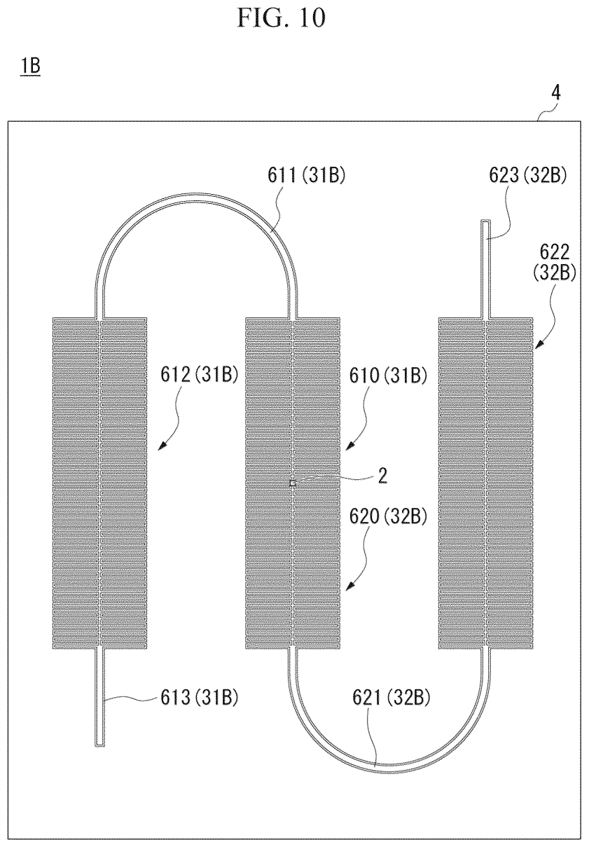

FIG. 10 is a diagram showing an example of a chip layout of a resonator 1B according to this example embodiment. The resonator 1B includes a junction element 2, a waveguide 31B, and a waveguide 32B. The junction element 2, the waveguide 31B, and the waveguide 32B are formed on a chip 4.

The waveguide 31B includes a fishbone-type waveguide 610, a meander-shaped CPW 611, a fishbone-type waveguide 612, and a linear CPW 613. The waveguide 32B includes a fishbone-type waveguide 620, a meander-shaped CPW 621, a fishbone-type waveguide 622, and a linear CPW 623. The fishbone-type waveguide 610 and the fishbone-type waveguide 620 are coupled by a junction element 2. The fishbone-type waveguide 610, the meander-type CPW 611, the fishbone-type waveguide 612, and the linear CPW 613 are coupled in series in this order from the junction element 2. The fishbone-type waveguide 620, the meander-type CPW 621, the fishbone-type waveguide 622, and the linear CPW 623 are coupled in series in this order from the junction element 2.

The length of each of the fishbone-type waveguide 610 and the fishbone-type waveguide 620 is, for example, about 300 μm. The length of each of the fishbone-type waveguide 612 and the fishbone-type waveguide 622 is, for example, about 600 μm. The radius of the meander-shaped CPW 611 and the meander-shaped CPW 621 is, for example, about 250 μm. The length of each of the linear CPW 613 and the linear CPW 623 is, for example, about 200 μm.

Therefore, in the resonator 1B, two waveguides are coupled by the junction element 2. Each of the two waveguides is a combination of a fishbone-shaped waveguide and a straight or curved CPW. The curved CPW may have a curved shape other than a meander-shape.

As in the resonator 1 according to the first example embodiment, the design of the quantum bit is limited to a linear structure in a case where using only a fishbone-shaped waveguide. On the other hand, as in the resonator 1B according to this example embodiment, by combining CPWs, the design of the quantum bit can be adapted to a wider variety of chip designs.

In addition, in the resonator 1B, a part of the quantum bit is composed of a thin CPW (meander-shaped CPW 611, linear CPW 613, meander-shaped CPW 621, and linear CPW 623). This allows an air bridge to be installed in the CPW part of the part that constitutes the waveguide 31B and the waveguide 32B. The air bridge can suppress the appearance of a resonance mode different from the design of the resonator, which may occur in a case where the waveguides are arranged in parallel.

Note that an air bridge is a structure made of a conductive material, for example, a metal, and electrically connects the GND planes on both sides of the core wire of the CPW. The air bridge does not contact the core wire, but has a structure that crosses the core wire three-dimensionally. Therefore, the air bridge and the core wire are not electrically connected. There is generally air or a vacuum between the air bridge and the core wire. In the case where the resonator is a superconducting quantum circuit (quantum bit) as in this example embodiment, there is a vacuum between the air bridge and the core wire. However, air bridges are generally fabricated using semiconductor process technology, and there is a possibility that dielectrics such as resist may remain around the air bridge during the fabrication process.

In addition, in the resonator 1B according to this example embodiment, an electric field node is formed near the center of the resonator, or in other locations depending on the design for the wavelength. As in the second example embodiment, in the resonator 1B, the tip of the control line can be placed at the position of the electric field node in the direction in which the phase of the electric field changes. In a case where placing the tip of the control line at the position of the electric field node, then as in the second example embodiment, the two fishbone-type waveguides are each coupled to the junction element 2 via a CPW, so that the control line can be extended to the vicinity of the junction element 2.

The layout of the resonator 1B shown in FIG. 10 is an example, and the waveguide may have a layout other than that shown in FIG. 10, as long as it is a combination of a fishbone-type waveguide and a straight or curved CPW. For example, the layouts of the waveguide 31B and the waveguide 32B may be different from each other. Moreover the lengths of the waveguide 31B and the waveguide 32B may be different from each other.

In the above-mentioned example embodiments, an example in which the waveguide in the quantum bit is a distributed constant type resonator has been described, but the present disclosure is not limited to this. In addition to distributed constant type resonators, lumped constant type resonators are also used for quantum bits. In a lumped constant type resonator, the resonance frequency is not simply determined from the relationship of the length of the resonator to the wavelength. In other words, in a lumped constant type resonator, the inductance and capacitance are determined according to the condition of the resonance frequency represented by the inductance and capacitance. However, since the resonator is not limited to a linear structure, it allows for a high degree of freedom in the design of the quantum bit. In addition, in general, the footprint of a quantum bit is smaller for a lumped constant type than for a distributed constant type. A fishbone-type waveguide can also be used for a quantum bit by configuring a resonator with a lumped constant type.

Therefore, in a resonator including a junction element made of a Josephson junction, and a fishbone-type waveguide coupled by the junction element, the fishbone-type waveguide may be a lumped constant type resonator.

In addition, in each of the above-mentioned example embodiments, an example in which the resonators 1, 1A, and 1B are quantum bits that form half-wavelength resonators has been described, but the disclosure is not limited to this. The resonators 1, 1A, and 1B may be used in superconducting circuits other than quantum bits.

The resonator 1, resonator 1A, and resonator 1B of this disclosure have been described above, but this disclosure is not limited to the above-mentioned example embodiments. The configuration and details of this disclosure may be modified in various ways that are understandable to a person skilled in the art within the scope of this disclosure.

While preferred example embodiments of the disclosure have been described and illustrated above, it should be understood that these are example embodiments of the disclosure and are not to be considered as limiting. Additions, omissions, substitutions, and other modifications can be made without departing from the scope of the present disclosure. Accordingly, the disclosure is not to be considered as being limited by the foregoing description, and is only limited by the scope of the appended claims.

A part or all of the above example embodiments may be described as, but are not limited to, the following supplementary notes.

### (Supplementary Note 1)

A resonator comprising:
a junction element including a Josephson junction; and
a fishbone-type waveguide coupled by the junction element.

### (Supplementary Note 2)

The resonator described in supplementary note 1, further comprising two fishbone-type waveguides, wherein the two fishbone-type waveguides are coupled by the junction element.

### (Supplementary Note 3)

The resonator described in supplementary note 1 or supplementary note 2, further comprising a control line magnetically coupled to the junction element and receiving a control signal, wherein a tip of the control line is located near a node of an electric field which is a standing wave generated in the resonator in a case where the resonator is in operation.

### (Supplementary Note 4)

The resonator described in supplementary note 3, wherein the tip of the control line is disposed near the junction element,
wherein the control line branches into a first branch line and a second branch line at the tip, and
wherein a length of the first branch line is shorter than a length of the second branch line.

### (Supplementary Note 5)

The resonator described in supplementary note 3 or supplementary note 4 wherein the two fishbone-type waveguides are each coupled to the junction element via a coplanar waveguide, and wherein the tip of the control line is disposed near the junction element.

### (Supplementary Note 6)

The resonator described in supplementary note 5 wherein the coplanar waveguide includes a first coplanar waveguide and a second coplanar waveguide, and
wherein a length of the second coplanar waveguide is shorter than a length of the first coplanar waveguide.

### (Supplementary Note 7)

A resonator according to any one of supplementary notes 1 to 6, wherein two waveguides are coupled by the junction element, and wherein each of the two waveguides is a combination of the fishbone-type waveguide and a straight or curved coplanar waveguide.

### (Supplementary Note 8)

The resonator according to supplementary note 1, wherein the fishbone-type waveguide is a lumped constant type resonant element.

### (Supplementary Note 9)

An oscillator that oscillates the resonator according to any one of supplementary notes 3 to 6, by passing an AC current through the control line.

### (Supplementary Note 10)

A method for manufacturing a resonator comprising coupling a fishbone-type waveguide to a junction element including a Josephson junction.

What is claimed is:

1. A resonator comprising:
a junction element including a Josephson junction; and
a fishbone-type waveguide coupled by the junction element.

2. The resonator according to claim 1, further comprising two fishbone-type waveguides,
wherein the two fishbone-type waveguides are coupled by the junction element.

3. The resonator according to claim 2, further comprising a control line magnetically coupled to the junction element and receiving a control signal,
wherein a tip of the control line is located near a node of an electric field, which is a standing wave generated in the resonator in a case where the resonator is in operation.

4. The resonator according to claim 3, wherein the tip of the control line is disposed near the junction element,
wherein the control line branches into a first branch line and a second branch line at the tip, and
wherein a length of the first branch line is shorter than a length of the second branch line.

5. The resonator according to claim 3, wherein the two fishbone-type waveguides are each coupled to the junction element via a coplanar waveguide, and
wherein the tip of the control line is disposed near the junction element.

6. The resonator according to claim 5, wherein the coplanar waveguide includes a first coplanar waveguide and a second coplanar waveguide, and
wherein a length of the second coplanar waveguide is shorter than a length of the first coplanar waveguide.

7. The resonator according to claim 2, wherein the two waveguides are coupled by the junction element, and
wherein each of the two waveguides is a combination of the fishbone-type waveguide and a straight or curved coplanar waveguide.

8. The resonator according to claim 1, wherein the fishbone-type waveguide is a lumped constant type resonant element.

9. An oscillator that oscillates the resonator according to claim 3, by passing an AC current through the control line.

10. A method for manufacturing a resonator comprising
coupling a fishbone-type waveguide to a junction element including a Josephson junction.

11. The method according to claim 10, further comprising two fishbone-type waveguides,
wherein the two fishbone-type waveguides are coupled by the junction element.

12. The method according to claim 11, further comprising a control line magnetically coupled to the junction element and receiving a control signal,
wherein a tip of the control line is located near a node of an electric field, which is a standing wave generated in the resonator in a case where the resonator is in operation.

13. The method according to claim 12, wherein the tip of the control line is disposed near the junction element,
wherein the control line branches into a first branch line and a second branch line at the tip, and
wherein a length of the first branch line is shorter than a length of the second branch line.

14. The method according to claim 12, wherein the two fishbone-type waveguides are each coupled to the junction element via a coplanar waveguide, and
wherein the tip of the control line is disposed near the junction element.

15. The method according to claim 14, wherein the coplanar waveguide includes a first coplanar waveguide and a second coplanar waveguide, and
wherein a length of the second coplanar waveguide is shorter than a length of the first coplanar waveguide.

16. The method according to claim 11, wherein the two waveguides are coupled by the junction element, and
wherein each of the two waveguides is a combination of the fishbone-type waveguide and a straight or curved coplanar waveguide.

17. The method according to claim 10, wherein the fishbone-type waveguide is a lumped constant type resonant element.
